(19) United States
(12) Patent Application Publication
(10) Pub. No.: US 2002/0050847 A1
(43) Pub. Date: May 2, 2002

(54) Semiconductor device with dummy interface circuit

(76) Inventors: Nobutaka Taniguchi, Kawasaki-shi (JP); Hiroyoshi Tomita, Kawasaki-shi (JP); Kota Hara, Kawasaki-shi (JP)

Correspondence Address: ARENT FOX KINTNER PLOTKIN & KAHN, 1050 CONNECTICUT AVENUE, N.W., SUITE 600, WASHINGTON, DC, 20036, US

(21) Appl. No.: 09/514,314

(22) Filed: Feb. 28, 2000

(30) Foreign Application Priority Data
Jun. 25, 1999 (JP) 11-180304

(51) Int. Cl. H03H 11/26

(52) U.S. Cl. 327/278

(57) ABSTRACT

A semiconductor device comprising a dummy interface circuit approximating to an external interface circuit with high accuracy is disclosed. The device further comprises a dummy interface circuit for internally generating, by simulation, a dummy output signal equivalent to the level of the output signal of the external interface circuit. The dummy interface circuit includes a dummy signal output circuit for producing a dummy output signal at a dummy output line, a dummy capacitor connected to the dummy output line, and a dummy load circuit connected to the dummy output line for converting the dummy output signal into a signal of a level corresponding to the output signal level of the external interface.

### BACKGROUND OF THE INVENTION

The present invention relates to a semiconductor device having a dummy interface circuit for simulating, in the device, an input/output circuit used for the interface intended to increase the speed by decreasing the signal amplitude, such as the “low voltage transistor-transistor logic (LVTTL)” or the “series stub termination logic (SSTL)” or, in particular, to the generation of a dummy output signal used in the DLL (delay locked loop) circuit for synchronizing the output timing with an external clock.

For conventional semiconductor devices, a plurality of interface standards are stipulated in order to maintain signal compatibility with other devices. A typical case is the TTL (transistor transistor logic). In a device such as the SDRAM (synchronous dynamic random access memory) or a device used in combination with the SDRAM, however, the two standards of LVTTL and SSTL with a reduced signal amplitude are commonly used for assuring a higher speed. With LVTTL, VIH is 2.0 V and VIL is 0.8 V, while with SSTL, VIH is Vref+0.2 V and VIL is Vref−0.2 V. In the description that follows, an SDRAM according to the SSTL standard is taken up as an example.

The data input/output for the SDRAM requires that the data be output in a predetermined phase with respect to an external clock. The data input/output speed is continually being increased. Taking the variations in the device characteristics, temperature change and the change in the source voltage into account, it has become difficult to accommodate the phase shift of the output timing within a tolerable range. Japanese Unexamined Patent Publication No. 10-112182 discloses an SDRAM having a DLL (delay locked loop) circuit capable of adjusting the phase of the internal clock for specifying the data output timing, in which the phase relation between the output data and the external clock is detected thereby to attain an optimum phase relation. It is actually difficult to detect the output data, and therefore a dummy interface circuit equivalent to an external interface circuit constituted of an output circuit and a device connected thereto is added for detecting the phase relation between the output and the external clock.

FIG. 1 is a diagram showing a basic configuration of the DLL circuit disclosed in Japanese Unexamined Patent Publication No. 10-112182.

As shown in FIG. 1, an external clock clk is input to a clock input buffer 1, an internal clock clki is generated and, by being phase adjusted in a DLL circuit 3, is produced as an output clock clkz. An output circuit 2 outputs the output data to an output terminal DQ in accordance with the output clock clkz. A dummy interface circuit 7 includes a dummy output circuit 8 for outputting a dummy signal to a dummy output line 9 in accordance with the output clock clkz, a dummy load capacitor 10 connected to the dummy output line 9, and a dummy input buffer 11 supplied with a dummy output signal applied to the dummy output line 9. A phase comparator 4 compares the phase of the internal clock clki with the phase of the output signal of the dummy input buffer 11 and outputs the result of comparison to a delay control circuit 6. The delay control circuit 6 changes the amount of delay in a variable delay element 5 based on the result of comparison. As a result, the phase of the output clock clkz changes, and when the phase of the internal clock clki and that of the output signal of the dummy input buffer 14 come to coincide with each other, the delay amount in the variable delay element 5 is determined. The conditions for each part of the dummy interface circuit 7 are set to assure the same change of the dummy output signal as if an output signal is applied to an external interface circuit under the standard conditions. Also, the dummy input buffer 11 is fabricated in such a manner as to produce the same delay amount as the clock input buffer 1.

In this way, in the DLL circuit of FIG. 1, the phase is regulated on the assumption that the dummy output signal generated in the dummy interface circuit 7 is equivalent to the output signal applied to the external interface circuit actually connected. The degree of this coincidence constitutes a major factor for improving the accuracy of phase adjustment of the output clock by the DLL circuit. Especially, the signal level of the dummy output signal is important, and a dummy output signal of the same level as the external interface circuit must be generated.

The dummy output circuit 8 includes a P-channel transistor and a N-channel transistor connected in series. In the case where the voltage at high potential side is set to the sum of the high level of the external interface circuit and the threshold voltage of the P-channel transistor, it is possible to produce a dummy output signal equal to the logic level on the high potential side of the external interface circuit. Once a logic level on the low potential side is generated in the dummy output circuit, however, the dummy output signal assumes a potential near to Vss (0 V), which is a potential different from the signal level of SSTL, for example.

Japanese Unexamined Patent Publication No. 10-285020 discloses a DLL circuit having a level conversion circuit for converting the dummy output signal of CMOS (TTL) level output from the dummy output circuit 8 to the signal of SSTL or LVTTL level. In this circuit, the dummy signal input to the dummy input buffer 11 constitutes the desired signal level, but the signal level output from the dummy output circuit is different from the desired signal level. Therefore, the dummy output signal cannot be said to be sufficiently approximate to the output signal of the external interface circuit, thereby posing the problem of the insufficient accuracy of phase adjustment.

The provision of a dummy interface circuit equivalent to the external interface circuit is a practice also carried out for circuits other than the DLL circuit and requires a high degree of coincidence.

### SUMMARY OF THE INVENTION

The object of the present invention is to provide a semiconductor device having a dummy interface circuit closely approximate to an external interface circuit.

FIGS. 2 to 4 are diagrams showing a basic configuration and operation waveforms of a semiconductor device according to the present invention.

In order to achieve the aforementioned object, according to the present invention, there is provided a semiconductor device comprising a dummy load circuit for converting a dummy output signal to a signal of a level corresponding to the output signal level of an external interface.

Specifically, the semiconductor device according to the invention comprises a dummy interface circuit 7 for internally generating, by simulation, a dummy output signal equivalent to the output signal level of the external interface, wherein the dummy interface circuit 7 includes a dummy signal output circuit 8 for outputting a dummy output signal to a dummy output line 9, a dummy capacitor 10 connected to the dummy output line 9, and a dummy load circuit 20 connected to the dummy output line 9 for converting the dummy output signal into a signal of a level corresponding to the output signal level of the external interface.

As shown in FIG. 2, the dummy load circuit 20 includes, for example, a pull-up circuit 21 connected to the dummy output line 9 through a first resistor 23 and a pull-down circuit 22 connected to the dummy output line 9 through a second resistor 24.

As is clear from the comparison between FIGS. 1 and 2, the DLL circuit of the semiconductor device according to the invention includes, in addition to the conventional configuration, a dummy load circuit 20 having the pull-up circuit 21, the pull-down circuit 22, the first resistor 23 and the second resistor 24.

For example, the pull-up circuit 21 is a constant voltage generating circuit for generating a predetermined voltage, and the pull-down circuit 22 is a ground line. By dividing the voltage with the resistors, the level of the dummy output signal can be converted to a signal level corresponding to the external interface. As a result, it is possible to generate a dummy output signal closely approximate to the external interface. In the case of a DLL circuit, therefore, the accuracy of phase adjustment can be improved.

In the dummy interface circuit 7 of FIG. 2, a constant current flows in the first and second resistors 23, 24, thereby posing the problem of an increased current consumption. As described above, if the dummy output circuit 8 is constituted of a circuit including a P-channel transistor and a N-channel transistor in series, a dummy output signal equal to the logic level on high-potential side of the external interface circuit can be easily output by appropriately setting the source voltage on high potential side of the dummy output circuit 8.

According to a second aspect of the invention, there is provided a semiconductor device in which the level of the dummy output signal on high potential side is realized as described above and only the level on low potential side is generated using the dummy load circuit. Specifically, the dummy load circuit is activated when the dummy output signal assumes one of the logic values, and deactivated when the dummy output signal assumes the other logic value. Specifically, as shown in FIG. 3, the pull-up circuit 21 and the pull-down circuit 22 making up the dummy load circuit are activated when the dummy output signal Dout is “low”, and deactivated when it is “high”. Thus, as long as the dummy output circuit 8 is configured of an invertor circuit including a P-channel transistor and a N-channel transistor in series, as shown in FIG. 4, the pull-up circuit 21 and the pull-down circuit 22 are turned off and the dummy output signal Dout rises to the high potential side due to the ability of the transistor (P-channel transistor) of the dummy output circuit 8 when the dummy output data Din is “low”. When the dummy output data Din is “high”, on the other hand, the pull-up circuit 21 and the pull-down circuit 22 are turned on, so that the dummy output signal Dout rises to a “low” level corresponding to the external interface by the transistor (N-channel transistor) of the dummy output circuit 8 and the dummy load circuit.

As a result, when the dummy output data Din is “low”, the pull-up circuit 21 and the pull-down circuit 22 are turned off, so that no current flows from the pull-up circuit 21 and the pull-down circuit 22 through the first and second resistors 23, 24, and therefore the power consumption is reduced.

As described above, with the configuration shown in FIG. 3, the power consumption can be reduced. When the dummy output Din is “high”, however, the pull-up circuit 21 and the pull-down circuit 22 are turned on, so that a current flows from the pull-up circuit 21 and the pull-down circuit 22 through the first and second resistors 23, 24. In the case of the DLL circuit, the phase of the rise or fall of the dummy output signal may be compared with the phase of an external clock. In such a case, the change of the rise or fall, as the case may be, is required to be similar to the change of the output signal of the external interface. The change of the other of the rise or fall, however, is not required to be accurate, but it is sufficient to change to a predetermined level until the next change of the rise or fall.

In view of this, according to the present invention, there is provided a semiconductor device comprising a dummy signal output circuit in which only one of the logic values of the dummy output signal is changed while the change of the dummy output signal to the other logic value is effected in a dummy load circuit.

### BRIEF DESCRIPTION OF THE DRAWINGS

The feature and advantages of the invention will be more clearly understood from the following description taken in conjunction with the accompanying drawings, in which:

FIG. 1 is a diagram showing a configuration of the conventional DLL circuit for synchronizing the output timing with an external clock;

FIG. 2 is a diagram showing a basic configuration of the DLL circuit according to the invention;

FIG. 3 is a diagram showing a basic configuration of a dummy load circuit according to the invention;

FIG. 4 is a time chart showing the operation of the dummy load circuit according to the invention;

FIG. 5 is a diagram showing a configuration of the DLL circuit according to a first embodiment of the invention;

FIG. 6 is a diagram showing a configuration of an output unit and a dummy output unit according to a second embodiment of the invention;

FIGS. 7A and 7B are diagrams showing models of an interface circuit;

FIG. 8A is a circuit diagram showing an output circuit;

FIG. 8B is a circuit diagram showing a dummy output circuit according to the second embodiment;

FIG. 9 is a circuit diagram showing a dummy load circuit according to the second embodiment;

FIG. 10 is a time chart showing the operation of the dummy interface circuit according to the second embodiment;

FIG. 11 is a circuit diagram of the dummy output circuit according to a third embodiment;

FIG. 12 is a circuit diagram of the dummy load circuit according to the third embodiment;

FIG. 13 is a diagram showing a circuit configuration of the dummy interface circuit according to a fourth embodiment; and

FIG. 14 is a time chart showing the operation of the dummy interface circuit according to the fourth embodiment.

### DESCRIPTION OF THE PREFERRED EMBODIMENTS

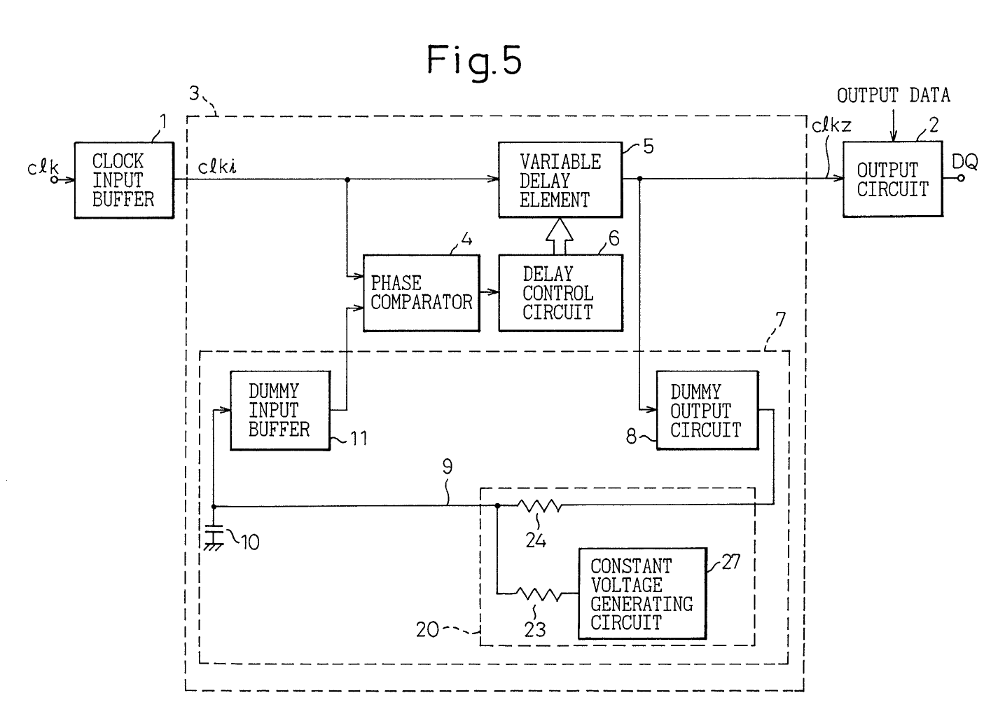

FIG. 5 is a diagram showing a configuration of a DLL circuit according to a first embodiment of the invention.

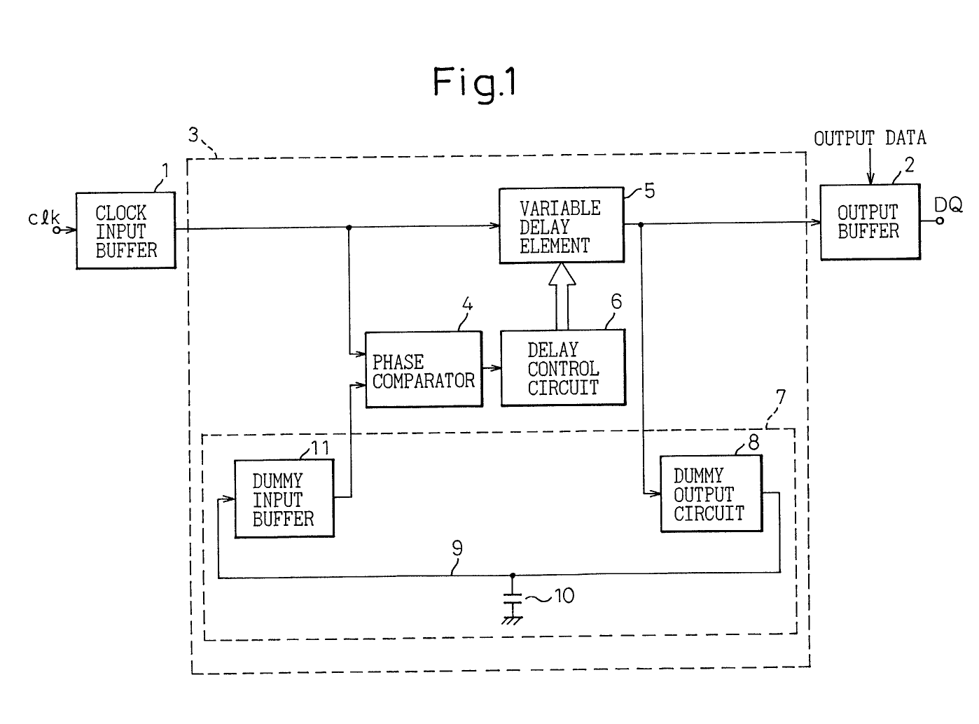

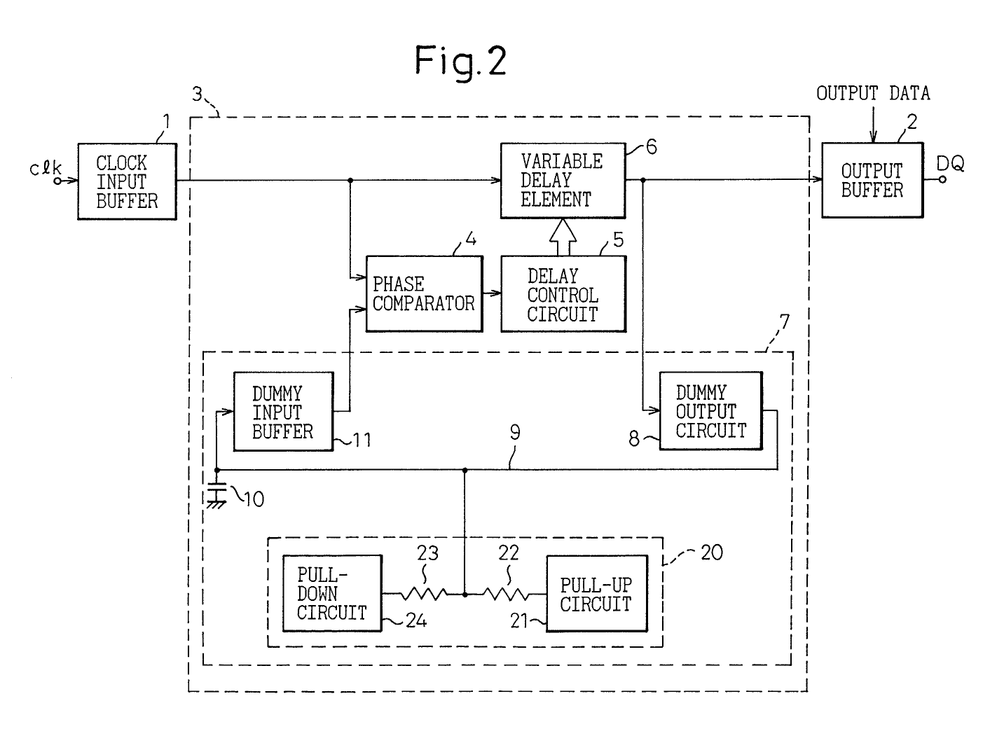

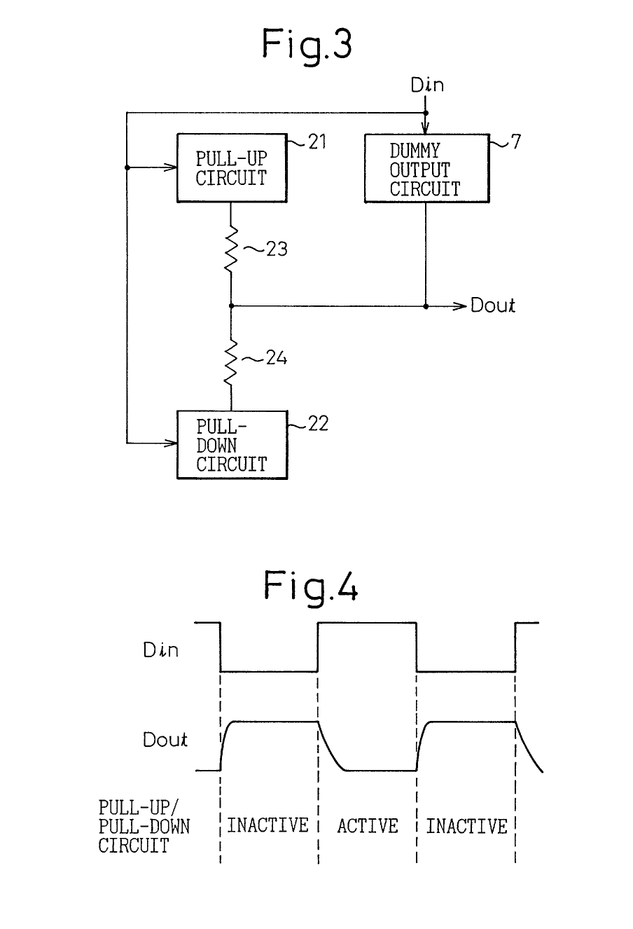

As clear from comparison between FIGS. 1 and 5, the DLL circuit 3 according to the first embodiment is different from the prior art in that the dummy interface circuit 7 includes a dummy load circuit 20 connected to the dummy output line 9. The dummy load circuit 20 includes a constant voltage generating circuit 27, a first resistor 23 connected to the constant voltage generating circuit 27 and the dummy output line 9, and a second resistor 24 connected to the dummy output circuit 8 and the dummy output line 9. The constant voltage produced from the constant voltage generating circuit 27 is equal to the power supply vtt of the external interface circuit, the resistance value of the first resistor 23 is set in accordance with the terminal resistor of the external interface, and the resistance value of the second resistor 24 is set in accordance with the stub resistance of the external interface. This dummy load circuit 20 causes the dummy output signal output from the dummy output circuit 8 to assume the same level as the level output from the output circuit 2 to the external interface.

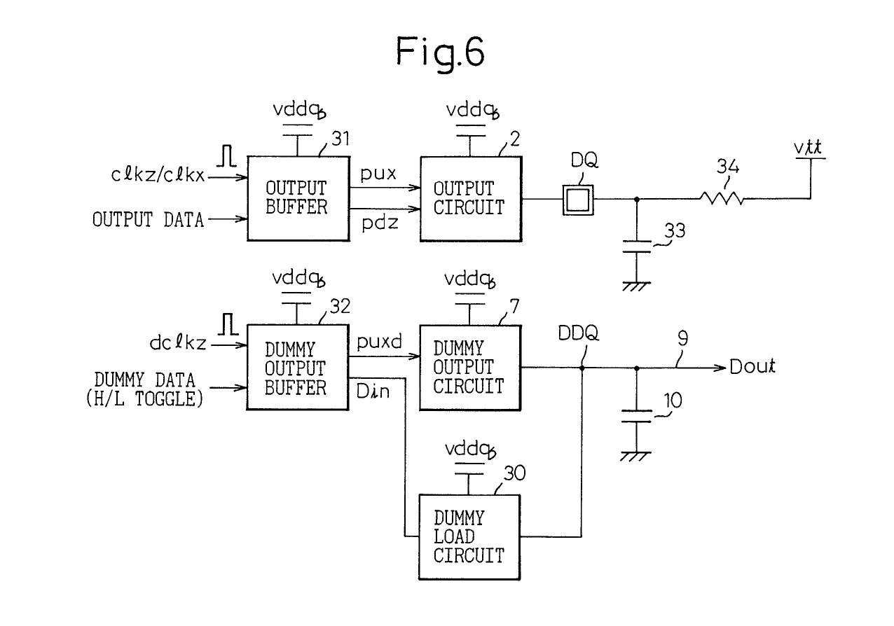

FIG. 6 is a diagram showing a configuration of the dummy interface circuit 7 of the SSTL standard according to the second embodiment of the invention, together with a regular output system. The dummy interface circuit of the second embodiment is also used with the DLL circuit for adjusting the output timing.

As shown in FIG. 6, the regular output system includes an output buffer 31 for generating the original output signals pux and pdz corresponding to the output data in accordance with the output clock clkz/clkx and an output circuit 2 having an output transistor for producing an output signal corresponding to the original output signal at the output terminal DQ. According to the SSTL standard, the output terminal DQ is connected to a power supply vtt through a terminal resistor 34 on the one hand and grounded through a load capacitor 33 of 30 pF on the other hand.

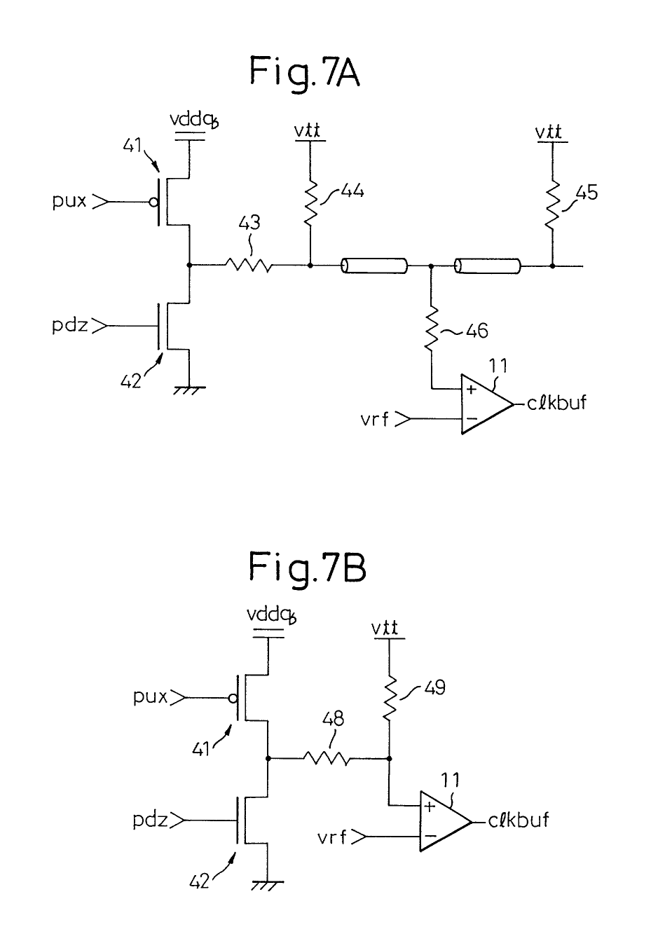

The manner in which the regular external interface circuit is simulated will be explained with reference to FIGS. 7A and 7B.

As shown in FIG. 7A, in the external interface of the SSTL standard, the output circuit 2 is an invertor circuit configured with a P-channel transistor 41 and a N-channel transistor 42 inserted in series between the power supply Vddq and the ground. The connecting node between the P-channel transistor 41 and the N-channel transistor 42 is connected to the transmission path through a stub resistor 43 of 25 Ω, and the transmission path is connected further to other devices. The two sides of the transmission path are connected to the power supply vtt through the terminal resistors 44 and 45. The external interface of the SSTL standard is configured this way. In the case of a dummy interface, a dummy input buffer 11 is connected midway of the transmission path through a stub resistor 46.

A transmission path cannot be formed in the device. According to the second embodiment, therefore, the configuration of FIG. 7A is realized by the dummy interface of the equivalent circuit as shown in FIG. 7B. Specifically, two terminals resistors 44 and 45 are combined into a dummy terminal resistor 49 of 25 Ω, while the stub resistors 43 and 46 are combined into a dummy stub resistor 48. Also, the dummy interface is simulated by scaling down the external interface in order to reduce the circuit space and the current consumption.

As shown in FIG. 6, the dummy interface includes a dummy output buffer 32 for generating the dummy original output signals puxd and Din corresponding to the dummy output data in accordance with the dummy output clock dclkz, a dummy output circuit 7 including a dummy output transistor for applying the dummy output signal corresponding to the original dummy output signal puxd to the dummy output line 9, a dummy capacitor 10 connected to the dummy output line 9 and a dummy load circuit 30 connected to the dummy output line 9. The dummy output line 9 is connected to a dummy input buffer 11. The operation of the dummy load circuit 30 is controlled in accordance with the dummy original output signal Din output from the dummy output buffer 32. The dummy output signal is a toggle signal which turns alternately between “high” and “low”, either within one cycle of an external clock clk or for each cycle of the external clock clk.

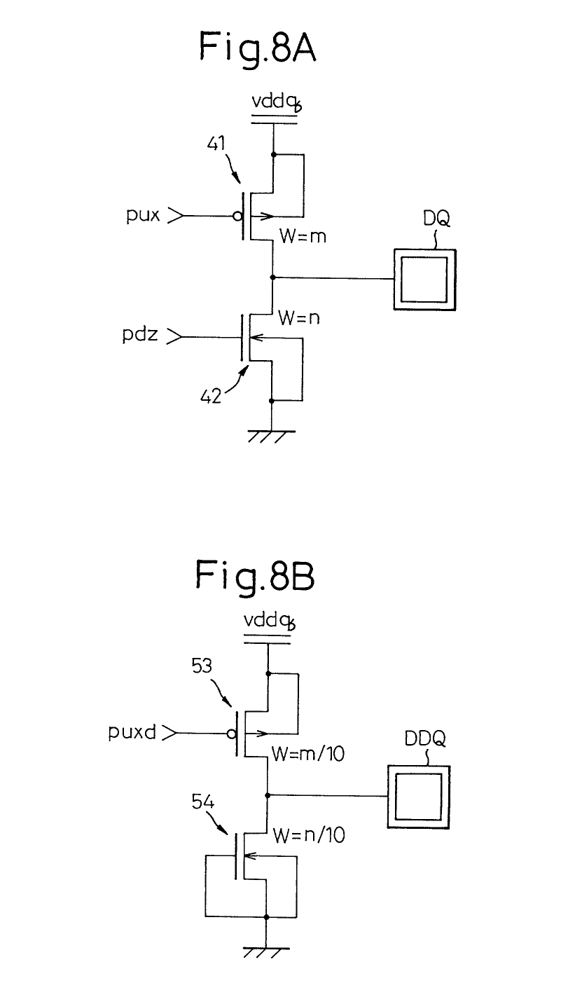

FIGS. 8A and 8B are diagrams for explaining the configuration of the dummy output circuit according to the second embodiment. FIG. 8A shows a configuration of the regular output circuit 2, and FIG. 8B a configuration of the dummy output circuit 7. As explained in FIG. 7, the regular output circuit 2 includes a P-channel transistor 41 and a N-channel transistor 42. The connecting node of the P-channel transistor 41 and the N-channel transistor 42 is connected to the output terminal DQ. The original output signals pux and pdz are applied to the gate of the P-channel transistor 41 and the gate of the N-channel transistor 42, respectively. In the case where the both the signals pux and pdz are “high”, the P-channel transistor 41 turns off and the N-channel transistor 42 turns on, so that the output signal produced at the output terminal DQ falls to a “low” level. In the case where the signals pux and pdx are both “low”, on the other hand, the P-channel transistor 41 turns on and the N-channel transistor 42 turns off, so that the output signal rises to “high” level. In the case where the signal pux is “high” and the signal pdz is “low”, the P-channel transistor 41 and the N-channel transistor 42 both turn off, so that the output assumes a high impedance. The state in which the signal pux is “low” and the signal pdz is “high” is prohibited. In this way, the output signal of the regular output circuit 2 turns “high”, “low” or assumes a high impedance in accordance with the original output signals pux and pdz.

FIG. 8B is a diagram showing a configuration of the dummy output circuit of the dummy interface circuit according to the second embodiment. As shown in FIG. 8B, an invertor is configured with a P-channel transistor 53 and a N-channel transistor 54 scaled down from the P-channel transistor 41 and the N-channel transistor 42, respectively, of the regular output circuit 2 of FIG. 8A. The gate of the P-channel transistor 53 is impressed with the dummy original output signal puxd and the gate of the N-channel transistor 54 is impressed with the ground voltage. As a result, the N-channel transistor 54 is kept in off state.

The DLL circuit using the dummy interface circuit according to the second embodiment compares only the edge changing when the dummy output signal rises and the leading edge of the external cock clk with each other. Thus, all that is necessary is that the leading edge of the dummy output signal accurately changes and no problem is posed whatever change the trailing edge thereof undergoes. In view of this, with the configuration as shown in FIG. 8B, the dummy output circuit 7 produces only a “high” level of the dummy output signal, and the “low” level output of the dummy output signal is produced by the dummy load circuit.

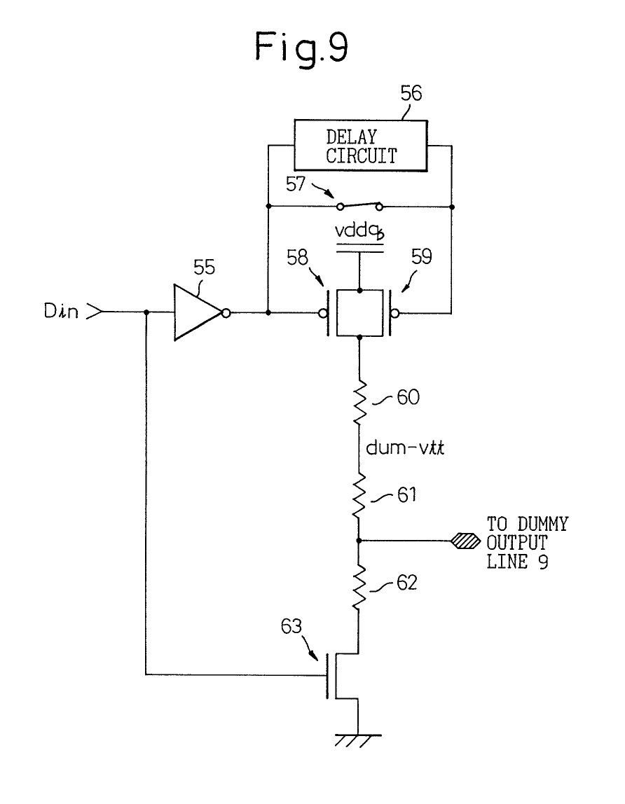

FIG. 9 is a diagram showing a configuration of a dummy load circuit. As shown in FIG. 9, a transfer gate including P-channel transistors 58, 59, a step-down resistor 60, a dummy terminal resistor 61, a dummy stub resistor 62 and an N-channel transistor 63 are connected in series between a power supply vddq and the ground. The dummy original output signal Din is applied to the gate of the N-channel transistor 63 on the one hand and to the gate of the P-channel transistor 58 through the invertor 55 on the other hand. The output of the invertor 55 is further applied through the switch 57 to the gate of the P-channel transistor 59. Also, a delay circuit is connected in parallel with the switch 57, so that the output of the invertor 55 is applied to the gate of the P-channel transistor 59 late in time. The step-down resistor 60, the dummy terminal resistor 61 and the dummy stub resistor 62 are set to 2 KΩ, 1 kΩ and 1 kΩ, respectively, in accordance with the scaling of the external interface. The step-down resistor 60 reduces the voltage value of the power supply vddq to dum-vtt (=vddq/2) equal to the terminal level of the external interface. In this way, the terminal level is generated using the power supply vddq.

The delay circuit 56 is inserted for the purpose of preventing the variation of the value dum-vtt under the charge share from the dummy output line 9 when the dummy original output signal Din turns “high” from “low”. For some time after the signal Din turns “low”, the P-channel transistor 59 is kept on to supply power from the power supply vddq thereby to reduce the variation of the value dum-vtt. Thus, the dummy load circuit is activated when the signal Din is “high”, and deactivated when the signal Din is “low”.

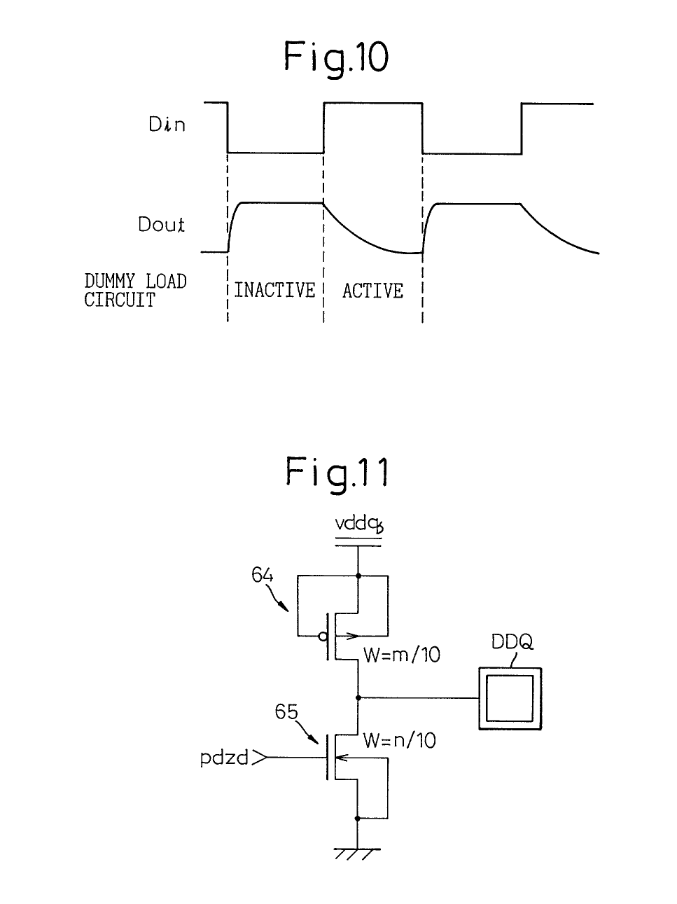

FIG. 10 is a time chart showing the operation of the dummy interface circuit according to the second embodiment. When the dummy original output signal Din turns “high” from “low”, the P-channel transistor 53 of the dummy output circuit 7 turns off, while the N-channel transistor 63 and the P-channel transistor 58 of the dummy load circuit 30 turn on. Thus, the potential of the dummy output line 9 changes toward the “low” level of SSTL. The dummy output circuit 30 does not contribute to this change at all, and the potential of the dummy output line 9, which is reduced only by the dummy load circuit 30, is changed slowly. It is sufficient if the potential of the dummy output line 9 changes to the “low” level of SSTL before the signal Din next turns “low”. The size of the N-channel transistor 63 and the P-channel transistors 58, 59 of the dummy load circuit 30 is set in such a manner as to meet the aforementioned condition in accordance with the period of the signal Din. Thus, the current, which flows to the ground from the power supply vddq through the transfer gate, the resistor and the N-channel transistor 63 while the signal Din is “high”, is minimized.

When the signal Din turns “low” from “high”, the N-channel transistor 63 and the P-channel transistor 58 turn off, then, the P-channel transistor 59 also turns off. At the same time, the P-channel transistor 53 of the dummy output circuit 7 turns on, so that the potential of the dummy output line 9 changes toward high potential (vddq) level of the dummy output circuit. Therefore, this change is similar to the rise from “low” level of SSTL. This change is effected only by the dummy output circuit 7, and the dummy load circuit 30 does not substantially contribute to the change nor consumes power.

As described above, it can be seen that the power consumption is small by reason of the fact that the dummy interface circuit according to the second embodiment generates a change equivalent to the external interface, and substantially no current flows therethrough.

The DLL circuit using the dummy interface circuit according to the second embodiment is the circuit for comparing the changing edge of the rising dummy output signal only with the leading edge of the external clock clk. It is sufficient therefore that the leading edge of the dummy output circuit changes accurately, and no problem is posed whatever change the trailing edge undergoes. Some DLL circuits, however, compare the changing edge of the falling dummy output signal only with the leading edge of the external clock clk. The dummy interface circuit according to the third embodiment is used for such a DLL circuit.

FIG. 11 is a diagram showing a configuration of the dummy output circuit of the dummy interface circuit according to the third embodiment. As shown in FIG. 11, an invertor is configured, as in the second embodiment, with the P-channel transistor 64 and the N-channel transistor 65 scaled down from the P-channel transistor 41 and the N-channel transistor 42, respectively, of the regular output circuit 2 of FIG. 8A. However, the gate of the N-channel transistor 65 is impressed with the dummy original output signal pdzd and the gate of the P-channel transistor 64 with the signal vddq. As a result, the P-channel transistor 64 is kept in off state.

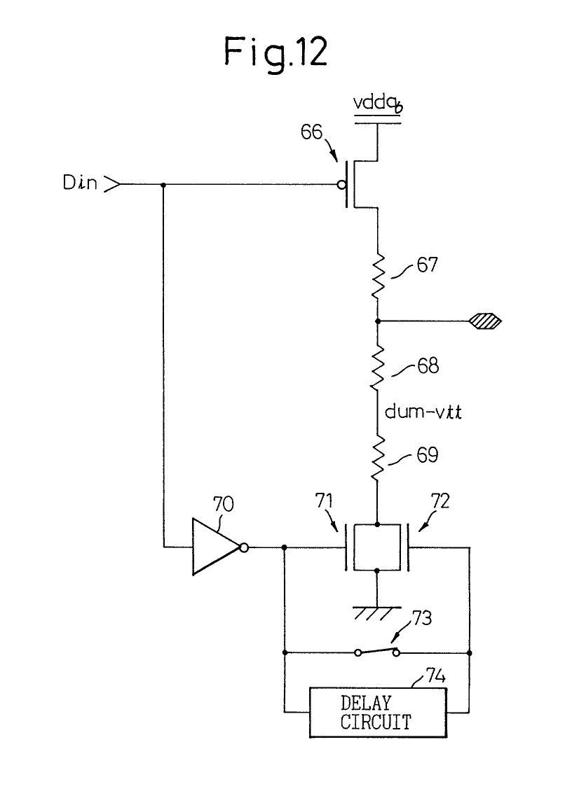

FIG. 12 is a diagram showing a configuration of a dummy load circuit of the dummy interface circuit according to a third embodiment. As is clear, when compared with FIG. 9, the third embodiment has a configuration of the circuit of FIG. 9 inverted symmetrically about the power supply. The configuration and operation will not be explained in detail. When the signal Din is “high”, the dummy load circuit is deactivated and the dummy output signal is changed to a low potential (vss) level of the dummy output circuit by the N-channel transistor 65 of the dummy output circuit of FIG. 11. When the signal Din is “low”, on the other hand, the dummy output circuit is turned off and the dummy output signal is changed slowly to a “high” level by the dummy load circuit. Thus, a signal level similar to the external interface is realized with a low power consumption.

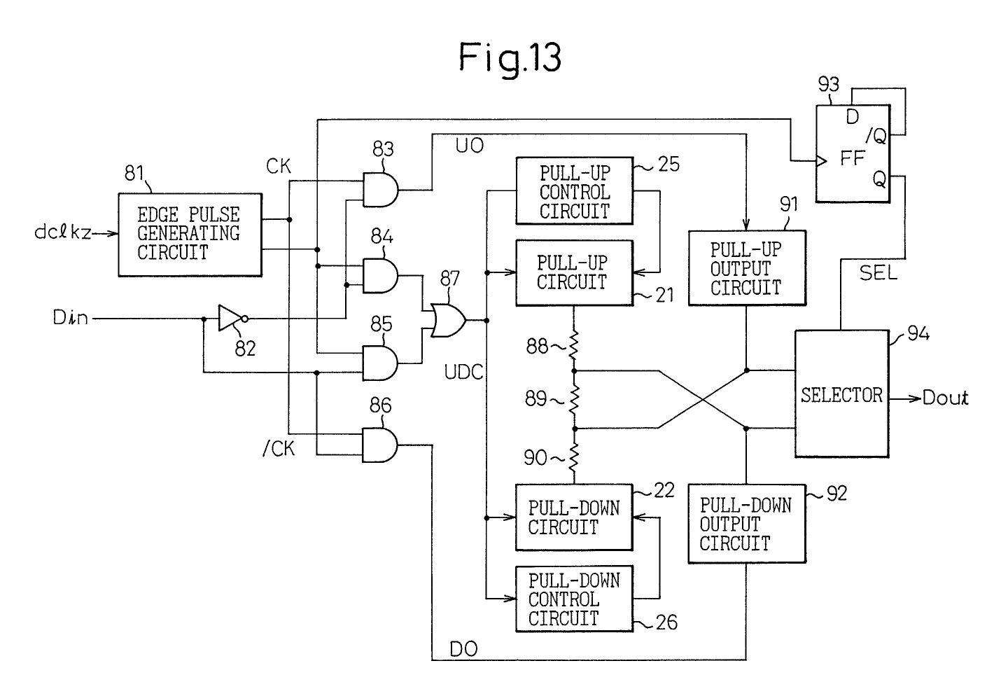

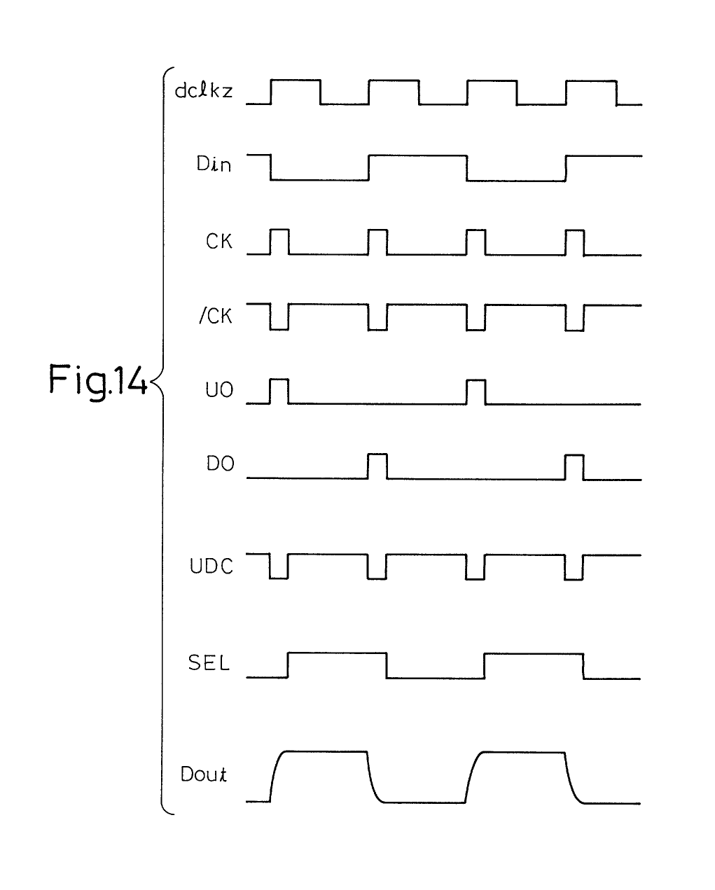

FIG. 13 is a diagram showing a configuration of the dummy interface circuit according to the fourth embodiment, and FIG. 14 is a time chart showing the operation of the same circuit.

A dummy interface circuit according to the fourth embodiment can accurately change both the leading edge and the trailing edge of the dummy output signal with a reduced power consumption. As shown in FIG. 13, the dummy output circuit includes a pull-up output circuit 91 and a pull-down output circuit 92. The pull-up output circuit 91, for example, is as shown in FIG. 8B and the pull-down output circuit 92 is as shown in FIG. 11. Also, the pull-up circuit 21 and the pull-down control circuit 25 are configured with the invertor 55, the P-channel transistors 58, 59, the switch 57 and the delay circuit 56 of FIG. 9, while the pull-down circuit 22 and the pull-down control circuit 26 are configured with the invertor 70, the N-channel transistors 71, 72, the switch 73 and the delay circuit 74 shown in FIG. 12. Also, the resistors 88 to 90 operate in combination as a dummy terminal resistor or a dummy stub resistor. The resistors 88 and 90 are set to 1 kΩ and the resistor 89 to 2 kΩ, for example.

Reference numerals 81 to 87 designate portions for generating a control signal for controlling the various parts from the dummy output clock dclkz and the dummy output data. A signal shown in FIG. 14 is generated. According to the fourth embodiment, the dummy output data Din is assumed to be a signal with the logic level thereof switching for each cycle of the dummy output clock dclkz. The edge pulse generating circuit 81 causes the auxiliary clocks CK, /CK to be generated from the dummy output clock dclkz. Four AND gates 83 to 86 and a NOR gate 87 generate a dummy original output signal UO applied to the pull-up output circuit 91, a dummy original output signal DO applied to the pull-down output circuit 92 and an active signal UDC applied to the pull-up circuit 21, the pull-up control circuit 25, the pull-down circuit 22 and the pull-down control circuit 26, from the auxiliary clocks CK, /CK, the dummy output data Din and the inverted signal thereof. Also, the flip-flop 93 generates a select signal SEL for controlling the selecting operation of the selector 94 by dividing the frequency of the clock /CK by one half. The output of the pull-up output circuit 91 is connected to the connecting node of the output resistors 89, 90, and the output of the pull-down output circuit 92 is connected to the connecting node of the resistors 88, 89, each being applied to the selector 94.

As shown in FIG. 14, when the signal Din falls to “low”, the signal UO rises to “high” for a short time, and the output of the pull-up output circuit 91 turns to “high” level. In the process, the selector 94 selects the output of the pull-up output circuit 91, and the dummy output signal Dout turns “high”. When the signal UO returns to “low” level, the pull-up output circuit 91 stops producing an output. At the same time, the active signal UDC turns “high”, thereby activating the pull-up circuit 21, the pull-up control circuit 25, the pull-down circuit 22 and the pull-down control circuit 26. Then the connecting node of the resistors 88, 89 starts to change toward the level corresponding to the “high” level of the external interface. At the same time, the selector 94 selects the output of the pull-down output circuit 92, and therefore the potential at the connecting node of the resistors 88, 89 is output as a dummy output signal Dout. In this case, too, it is sufficient if the potential of the connecting node of the resistors 88, 89 turns to “high” level of the external interface before the signal Din turns “high”. When the signal Din turns “high”, the signal UDC falls to “low”, thereby deactivating the pull-up circuit 21, the pull-up control circuit 25, the pull-down circuit 22 and the pull-down control circuit 26. At the same time, the signal DO turns “high” for a short length of time, and the pull-down output circuit 92 turns on, the output of which turns “low”. When the signal DO returns to “low” level, the pull-down output circuit 92 stops the output (changes the output → to be Hi-impedance). At the same time, the active signal UDC turns “high”, thereby activating the pull-up circuit 21, the pull-up control circuit 25, the pull-down circuit 22 and the pull-down control circuit 26. The connecting node of the resistors 88, 89 thus starts changing toward a level corresponding to the “low” level of the external interface. At the same time, the selector 94 selects the output of the pull-up output circuit 91, and therefore the potential at the connecting node of the resistors 88, 89 is output as a dummy output signal Dout. Subsequently, a similar operation is repeated, thus producing a dummy output signal such as that designated by Dout in FIG. 14.

This dummy output signal rises from the “low” level of the external interface and falls from the “high” level of the external interface. Therefore, the timing can be compared by the two changing edges. The pulse width of the signals UO and DO can be set appropriately, and the power consumption can be reduced by shortening the “high” period of the signal UDC during which a current flows in the pull-up circuit 21 and the pull-down circuit 22. In a similar manner, the power consumption can be reduced by reducing the power supply capacity of the pull-up circuit 21 and the pull-down circuit 22 and changing it to a predetermined level immediately before the change of the signal Di.

It will thus be understood from the foregoing description that according to the invention, a dummy interface circuit of low power consumption approximating to an external interface circuit with high accuracy can be realized. As a result, the accuracy of the timing adjustment of the DLL circuit, etc. can be improved for a higher operating speed of the semiconductor devices.

What is claimed is:

1. A semiconductor device comprising a dummy interface circuit for internally generating by simulation a dummy output signal equivalent to the level of the signal output to an external data bus, wherein said dummy interface circuit includes:
a dummy signal output circuit for producing said dummy output signal to a dummy output line;
a dummy capacitor connected to said dummy output line; and
a dummy load circuit connected to said dummy output line for converting said dummy output signal into a signal of a level corresponding to the level of said output signal.

2. A semiconductor device according to claim 1, wherein said dummy load circuit includes a pull-up circuit connected to said dummy output line through a first resistor, and a pull-down circuit connected to said dummy output line through a second resistor.

3. A semiconductor device according to claim 1, wherein said dummy load circuit is activated when said dummy output signal assumes one of logic values and deactivated when said dummy output signal assumes the other logic value.

4. A semiconductor device according to claim 2, wherein said dummy load circuit is activated when said dummy output signal assumes one of logic values and deactivated when said dummy output signal assumes the other logic value.

5. A semiconductor device according to claim 1, wherein said dummy signal output circuit changes said dummy output signal to only one of the logic values.

6. A semiconductor device according to claim 2, wherein said dummy signal output circuit changes said dummy output signal to only one of the logic values.

7. A semiconductor device according to claim 3, wherein said dummy signal output circuit changes said dummy output signal to only one of the logic values.

8. A semiconductor device according to claim 4, wherein said dummy signal output circuit changes said dummy output signal to only one of the logic values.

9. A semiconductor device according to claim 1, wherein:
said dummy signal output circuit includes a pull-up output circuit for raising the level of said dummy output signal and a pull-down output circuit for lowering the level of said dummy output signal; and
said dummy load circuit includes a pull-up circuit connected to said dummy output line through a first resistor and reduced equivalently to said pull-up output circuit or to a predetermined ratio, and a pull-down circuit connected to said dummy output line through a second resistor and reduced equivalently to said pull-down output circuit or to said predetermined ratio.

10. A semiconductor device according to claim 1, wherein:
said dummy signal output circuit includes a pull-up output circuit for raising the level of said dummy output signal and a pull-down output circuit for lowering the level of said dummy output signal;
said dummy load circuit includes a pull-up circuit reduced equivalently to said pull-up output circuit or to a predetermined ratio, a pull-down circuit reduced equivalently to said pull-down output circuit or to a predetermined ratio, and first, second and third resistors connected in series between said pull-up circuit and said pull-down circuit;
said pull-down output circuit is connected to the connecting node of said first resistor and said second resistor; and
said pull-up output circuit is connected to the connecting node of said second resistor and said third resistor.
